(19) United States
(12) Patent Application Publication
(10) Pub. No.: US 2026/0221718 A1
(43) Pub. Date: Jul. 30, 2026

(54) TEMPERATURE REGULATION OF LASER ASSEMBLIES

(71) Applicant: Telefonaktiebolaget LM Ericsson (PUBL), Stockholm (SE)

(72) Inventors: Claudio D'INCÀ, Genova (IT); Alberto DEHO, Genova (IT); Sergio MOSTI, Genova (IT)

(21) Appl. No.: 19/150,470

(22) PCT Filed: Jan. 26, 2023
(86) PCT No.: PCT/EP2023/051955

§ 371 Date: Jul. 23, 2025

(51) Int. Cl. H01S 5/024; H01S 5/00

(52) U.S. Cl. CPC H01S 5/02453; H01S 5/0014; H01S 5/02415

(57) ABSTRACT

In an embodiment, a laser assembly (100, 200) comprises a laser chip (102, 202), a heater (104, 204), a temperature regulation device (106, 206) capable of heating and cooling the laser chip (102, 202), at least one temperature sensor (108, 208) configured to measure a temperature of the laser assembly (100, 200) and a controller (110, 210). The controller (110, 210) is configured to, based on at least one temperature measured by the at least one temperature sensor (108, 208), control the heater (104, 204) to heat the laser chip (102, 202); and control the temperature regulation device (106, 206) to regulate the temperature of the heated laser chip (102, 202).

### TECHNICAL FIELD

The present disclosure relates to temperature regulation of a laser chip of a laser apparatus and in particular to methods, apparatus and machine readable medium encoding instructions to regulate a temperature of a laser chip.

### BACKGROUND

The wavelength of light output by lasers can change with their temperature. Therefore, laser assemblies may be associated with temperature regulation devices such that the laser produces light at an intended wavelength, regardless of the temperature in the environment and/or any self-heating within the laser assembly or the like.

To provide thermal stability (and therefore wavelength stability) of a laser assembly, and in particular to a light producing component thereof (herein referred to as a laser chip), temperature regulation devices such as Peltier devices may be used. Such devices may heat or cool components of the laser assembly. However, where there is a wide range of possible environmental temperatures in which a laser assembly is to operate, it may be the case that Peltier devices with large dimensions may be used, or multiple smaller Peltier devices may be used. This can add size and complexity to a laser assembly.

For example, in relation to dense wavelength-division multiplex (DWDM) telecommunications lasers, a temperature of operation T₀ may be specified for the laser chip, which may for example be in a temperature range 35-55° C., with T₀ being determined within such a range in a calibration operation, as the temperature which produces light at the intended wavelength. In normal operation of the laser assembly, it may be intended that the temperature of a laser chip is maintained within a temperature band about T₀, for example within +/−2° C., or +/−1° C. of T₀.

Moreover, it may be intended that laser assemblies should be capable of operating in a wide range of environmental temperatures, for example from −40 to +85° C., such that they can be employed in diverse industrial and natural environments.

This presents a challenge for the temperature regulation apparatus. Considering an example where the laser chip is to operate at a temperature T₀ of 55° C. to produce light at a specified frequency, and the environmental temperature is −40° C., a dT value of 95° C. is needed, with precise temperature regulation once this difference has been established.

### SUMMARY

Certain aspects and embodiments described herein may provide a low cost and simple solution for enabling laser assemblies to be operated in a range of environmental temperatures whilst maintaining a specified temperature and while reducing or obviating problems with existing solutions.

According to a first aspect of the present disclosure, there is provided a laser assembly comprising a laser chip, a heater and a temperature regulation device. The temperature regulation device is capable of heating and cooling the laser chip. The laser assembly further comprises at least one temperature sensor. The temperature sensor(s) is/are configured to measure a temperature of the laser assembly, for example a temperature of the laser chip. The laser assembly further comprises a controller. The controller is configured to, based on at least one temperature measured by the temperature sensor(s), control the heater to heat the laser chip and control the temperature regulation device to regulate the temperature of the heated laser chip.

According to a second aspect of the present disclosure, there is provided a method of regulating the temperature of a laser chip of a laser assembly. The method comprises heating the laser chip using a heater of the laser assembly. The method further comprises sensing a temperature of the laser chip. The method further comprises, based on a difference between the sensed temperature and at least one set point temperature, controlling the temperature of the heated laser chip using a temperature regulation device which is capable of heating and cooling the laser chip.

According to a third aspect of the present disclosure, there is provided a machine readable medium encoding instructions for regulating a temperature of a laser chip of a laser assembly. The instructions, when executed by a processor of a laser assembly, cause the processor to heat the laser chip using a heater of the laser assembly. The instructions further cause the processor to determine a temperature of the laser chip. The instructions further cause the processor to, based on a difference between the sensed temperature and at least one set point temperature, control the temperature of the heated laser chip using a temperature regulation device which is capable of heating and cooling the laser chip.

Certain embodiments of the present disclosure may provide one or more of the following technical benefits. Certain embodiments may facilitate the use of a single temperature regulation device which is capable of cooling a laser chip. Certain embodiments may facilitate the use of smaller temperature regulation devices which is/are capable of cooling a laser chip. Some embodiments may be relatively low cost to deploy whilst also providing a less complex apparatus. Certain embodiments may improve the efficiency of heat transfer to the laser chip relative to use of a Peltier device without a heater. Certain embodiments may lower the power consumption of the device.

This summary is not an extensive overview of all contemplated embodiments and is not intended to identify key or critical aspects or features of any or all embodiments or to delineate the scope of any or all embodiments. In that sense, other aspects and features will become apparent to those ordinarily skilled in the art upon review of the following description of specific embodiments in conjunction with the accompanying Figures.

### BRIEF DESCRIPTION OF THE DRAWINGS

Exemplary embodiments will be described in more detail with reference to the following Figures, in which:

FIG. 1A and B are schematic diagrams illustrating an apparatus for regulating the temperature of a laser chip according to an embodiment, showing a side view and a top view respectively.

FIG. 2 is a schematic diagram illustrating an apparatus for regulating the temperature of a laser chip according to an embodiment.

FIG. 3 is a schematic diagram illustrating a controller and control loops according to an embodiment.

FIGS. 4 to 7 are flowcharts of methods of regulating the temperature of a laser chip according to embodiments.

FIG. 8 is a schematic diagram illustrating a machine-readable medium for regulating the temperature of a laser chip according to an embodiment.

### DETAILED DESCRIPTION

The embodiments set forth below represent information to enable those skilled in the art to practice the embodiments. Upon reading the following description in light of the accompanying Figures, those skilled in the art will understand the concepts of the description and will recognize applications of these concepts not particularly addressed herein. It should be understood that these concepts and applications fall within the scope of the description.

In the following description, numerous specific details are set forth. However, it is understood that embodiments may be practiced without these specific details. In other instances, well-known circuits, structures, and techniques have not been shown in detail in order not to obscure the understanding of the description. Those of ordinary skill in the art, with the included description, will be able to implement appropriate functionality without undue experimentation.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to implement such feature, structure, or characteristic in connection with other embodiments whether or not explicitly described.

As used herein, the singular forms “a”, “an” and “the” are intended to include the plural forms as well, unless the context clearly indicates otherwise. It will be further understood that the terms “comprises,” “comprising,” “includes,” and/or “including” when used herein, specify the presence of stated features, integers, steps, operations, elements, and/or components, but do not preclude the presence or addition of one or more other features, integers, steps, operations, elements, components, and/or groups thereof.

As already discussed, existing solutions for thermal stabilization of laser chips comprise the use of a temperature regulation device or devices. However, considering the requirements of the temperature regulation devices and the industrial environmental conditions, this may not always be an efficient, low cost or low complexity solution.

Hence, there is a need to provide a relatively low cost, low complexity solution for enabling thermal stabilization of laser chips while reducing or obviating problems with existing solutions.

Certain embodiments described herein may offer a solution to one or more of the problems highlighted herein.

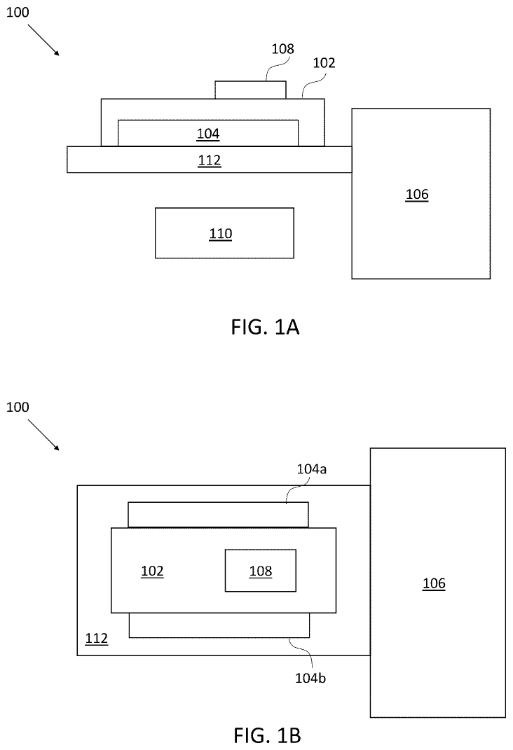

FIG. 1A and FIG. 1B are schematic diagrams illustrating a laser assembly 100 according to an embodiment. For example, the laser assembly 100 may comprise a dense wavelength-division multiplex (DWDM) laser. In some examples, the laser assembly 100 may comprise a telecommunications laser assembly, for example for transmitting an optical signal via free space, or via an optical fiber. The laser assembly 100 may comprise part of a Small Form-factor Pluggable (SFP) network interface module.

The laser assembly 100 comprises a laser chip 102. The laser chip 102 may for example comprise electronic components capable of producing laser light. For example, the laser chip 102 may comprise a semiconductor laser chip, for example comprising a laser diode. In some examples, the laser chip 102 may comprise a Distributed-feedback (DFB) laser, Fabry-Perot laser or a Vertical-Cavity Surface-Emitting Laser (VCSEL), which is capable of producing laser light, and which is formed as a chip. In a particular example, the laser chip 102 may be capable of operating as a DWDM DFB laser. In this example, the laser chip 102 is formed on a substrate 112, which may for example comprise a silicon substrate, and which provides a mounting for the laser chip 102.

The laser assembly 100 further comprises at least one heater 104, and in this example there are two heaters 104a, 104b, as can be seen from FIG. 1B, one positioned on either side of the laser chip 102. For example, the heater(s) 104 may be positioned in close proximity to, or in contact with, the laser chip 102. For example, the heater(s) 104 may be included in a transmitter optical sub assembly (TOSA) of a telecommunications laser assembly. The heater 104 may be a resistor. Such a heater 104 may be formed in the substrate 112, for example being etched into the substrate 112. In some examples one heater 104 may be provided while in still other examples, further heaters 104 may be provided. Providing more than one heater 104, and/or heater(s) in close proximity to the laser chip 102 may provide for more efficient and/or even heating of the laser chip 102.

The laser assembly 100 further comprises a temperature regulation device 106. The temperature regulation device 106 is capable of heating and cooling the laser chip 102. The temperature regulation device 106 may comprise a thermoelectric cooler (TEC) such as a Peltier device or Peltier cooler. As noted above, such devices are referred to as ‘coolers’ but are capable of both heating and cooling the laser chip 102 (as when they are heating the laser chip 102, they are cooling another component such as a heat sink). This is in contrast to the heater(s) 104, which can heat the laser chip 102, but cannot provide active cooling of the chip 102. It may be noted that, in this example, the temperature regulation device 106 is in physical contact with the substrate 112 and is somewhat spaced from the laser chip 102 (and at a greater distance from the laser chip 102 than the heater(s) 104).

The laser assembly 100 further comprises at least one temperature sensor 108. The temperature sensor 108 is configured to measure a temperature of the laser assembly 100. The temperature sensor 108 may for example comprise a thermistor, or some other temperature sensor. In this example, the temperature sensor 108 is mounted directly on the laser chip 102 (and may be integral thereto) and may therefore be described as a laser chip temperature sensor 108. In other examples, as set out below, an environmental temperature sensor may be provided alternatively or in addition to the laser chip temperature sensor 108.

The laser assembly 100 further comprises a controller 110. The controller 110 may comprise processing circuitry, for example comprising at least one processor.

The controller 110 is configured to, based on at least one temperature measured by the temperature sensor 108, control the heater 104 to heat the laser chip 102 and control the temperature regulation device 106 to regulate the temperature of the heated laser chip 102.

The controller 110 may be configured to control the at least one heater 104 and the temperature regulation device 106 to heat the laser chip 102 in response to a determination that the laser chip temperature is below a predetermined value. The controller 110 may further be configured to control the temperature regulation device 106 to regulate the temperature of the heated laser chip 102 once the laser chip temperature has reached a predetermined value. The controller 110 may comprise a TEC controller.

In examples herein, heater(s) 104 act to provide a temperature difference between an operating environment and the laser chip, which may then be further controlled, or ‘fine-tuned’ by the temperature regulation device 106. This may therefore allow the temperature regulation device 106, which may be a more complex device than the heater 104 (for example the temperature regulation device 106 may comprise a Peltier device whereas the heater 104 may comprise a resistor or the like), to be smaller or less powerful than if it were performing temperature regulation alone, thus reducing the size and/or complexity of the laser assembly 100 as a whole.

In some examples, the controller 110 may be configured to control the heater 104 using a first control loop and to control the temperature regulation device 106 using a second control loop. In some examples, the first control loop has a lower set point temperature than the second control loop. In other examples, the set point temperatures of the control loops may be the same. In some examples, the first control loop has a different (e.g. greater) temperature tolerance than the second control loop.

In some examples, the first control loop may be carried out with a first repetition rate, whereas the second control loop may be carried out with a second repetition rate. For example, in the first control loop, a temperature may be acquired every X seconds, and a control applied to the heater(s) 104 if the temperature is different from (or in some examples less than) a temperature set point of the first control loop. However, in the second control loop, a temperature may be acquired every Y seconds, and a control applied to the temperature regulation device 106 if the temperature is different from a temperature set point of the second control loop. The second repetition rate may be greater than the first repetition rate (or put another way, Y may be less than X) such that the control loop applied to the temperature regulation device 106 is generally more responsive than the control loop applied to the heater 104. However, in other examples, first repetition rate may be greater than the second repetition rate.

In an example, heater(s) 104 may act as a coarse temperature setting while the temperature regulation device 106 may act as a fine temperature setting. The heater(s) 104 may establish a working temperature for the laser chip 102, for example, within ±20° C., ±10° C. or ±5° C. of a predetermined target temperature. In other examples, the heater(s) 104 may establish a working temperature of the laser chip 102 which heats the chip 102 relative to the environment but regulates the temperature of the laser chip 102 to be lower than a target temperature of the chip, for example by around 20° C., 10° C. or 5° C. The temperature regulation device 106 may establish a fine regulation of the laser chip temperature, for example within ±1° C., or ±2° C., of the predetermined target temperature by heating and/or cooling. The predetermined target temperature and/or the temperatures indicating the ends of the tolerance ranges may be referred to as set point temperatures.

The laser assembly 100 may in some examples comprise additional components not shown herein, for example comprising a mirror positioned at the end of the laser chip 102. In addition, a photodiode may be provided to monitor the power of laser light output. Moreover, the laser assembly 100 may comprise a Printed Circuit board (PCB), which is electrically connected to the components thereof, for example via a flex circuit board.

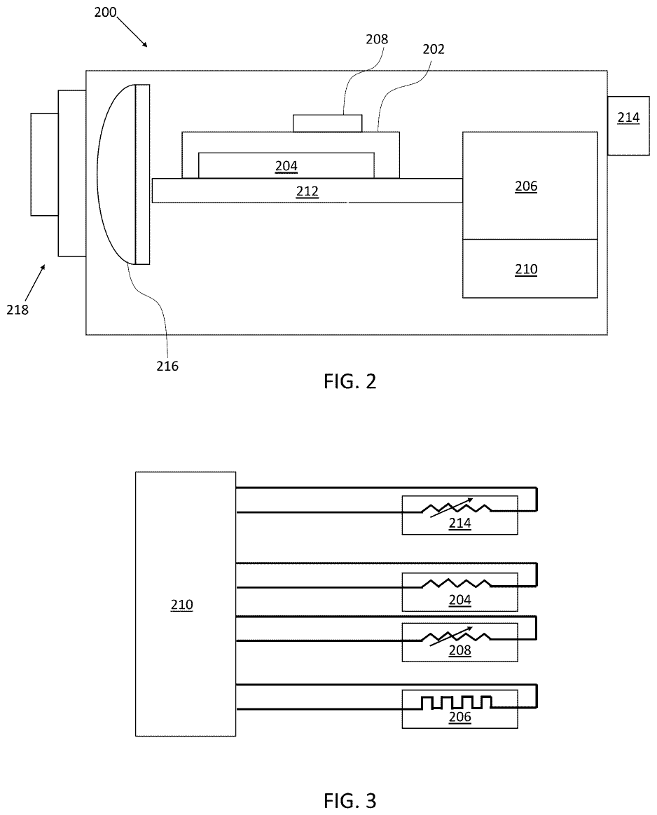

FIG. 2 is a schematic diagram illustrating a laser assembly 200 for regulating a temperature of a laser chip 202 according to an embodiment. The laser assembly 200 comprises a laser chip 202, at least one heater 204, a temperature regulation device 206, a laser chip temperature sensor 208, a controller 210 and a substrate 212. These components may have any of the features of the corresponding components described in relation to FIGS. 1A and 1B. The laser assembly 200 may comprise a DWDM telecommunications laser assembly.

The laser assembly 200 in this example further comprises an environmental temperature sensor 214 to measure an environmental temperature of the laser assembly 200. For example, such a temperature sensor may be mounted on a housing of the laser assembly 200.

In an example, the controller 210 may be configured to control the heater 204 to heat the laser chip 202 in response to a determination that the environmental temperature is below a predetermined value and control the temperature regulation device 206 to regulate the temperature of the heated laser chip 202 once the laser chip temperature has reached a predetermined value.

In this example the laser assembly 200 comprises an optical fiber telecommunications laser. This comprises a lens 216 and a fiber coupler 218, to allow the laser assembly 200 to be attached to an optical fiber, and to focus light into an attached fiber. The laser assembly 200 may in some examples comprise additional components not shown herein, for example comprising a mirror positioned at the end of the laser chip 202 which is distal to the lens 216, to reflect laser light toward the lens 216. In addition, a photodiode may be provided to monitor the power of laser light output. Moreover, the laser assembly 200 may comprise a Printed Circuit board (PCB), which is electrically connected to the components thereof, for example via a flex circuit board. Other components may be provided in other examples.

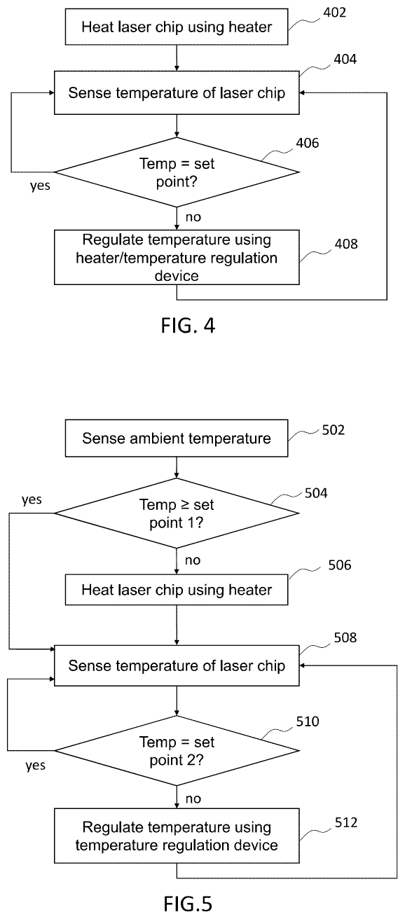

FIG. 3 is a schematic diagram illustrating the inputs and outputs of the controller 210. The laser chip temperature sensor 208, which in this example is a thermistor (i.e. a resistive element, wherein the resistance changes based on the temperature, and therefore illustrated as a variable resistor) is used to detect the temperature of the laser chip 202. The environmental temperature sensor 214 (a second thermistor) is positioned further away from the laser chip 202 than the laser chip temperature sensor 208 to detect a temperature more closely resembling the ambient temperature.

The controller 210 is configured to control the heater 204 to heat the laser chip 202 in response to a determination that at least one temperature (which may be the temperature of the laser chip and/or the ambient temperature) is below a predetermined value (at least to within a predetermined temperature range). Moreover, the controller 210 is to control the temperature regulation device 206 to regulate the temperature of the heated laser chip 202 based on a determination that the temperature of the laser chip 202 does not meet a predetermined value (at least to within a predetermined temperature range).

As illustrated in FIG. 3, in this example, the heater 204 is a resistor. This may therefore be controlled to heat the laser chip 202 by providing power to the heater 204 and may for example be controlled using on/off control, amount of power supplied, pulse width modulation or the like. The temperature regulation device 206 may be a Peltier device or the like, and may for example be controlled using on/off control, or pulse width modulation, of the temperature regulation device 206. Such control methods may also be used with the heater(s) 104 and the temperature regulation device 106 described in relation to FIGS. 1A and 1B.

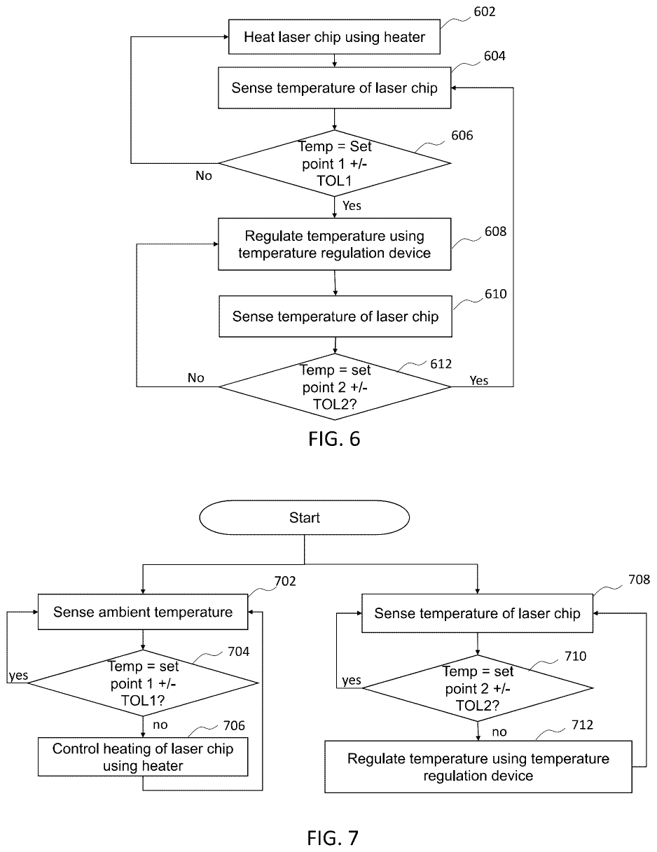

FIGS. 4 to 7 illustrate methods of regulating a temperature of a laser chip 102 of a laser assembly 100. The laser assembly may be the laser assembly of FIGS. 1A and 1B, or the laser assembly of FIG. 2, and the method may be carried out under the control of a controller of a laser assembly (e.g. controller 110, 210).

In FIG. 4, block 402 comprises heating the laser chip using a heater of the laser assembly. The laser chip may for example comprise a laser chip 102, 202 as described above. The heater may for example comprise at least one heater 104, 204 as described above. In some examples, such heating may be triggered based on a sensed temperature, wherein the sensed temperature may be a temperature of a laser chip and/or an ambient temperature.

Block 404 comprises sensing a temperature of the laser chip. This may be carried out using at least one temperature sensor, for example a laser chip temperature sensor 108, 208 as described above.

Block 406 comprises determining whether the temperature of the laser chip is equal to a set point temperature, at least to within a predetermined tolerance. The set point temperature may be the target operating temperature of the laser chip, which may for example, as set out above, be determined for a laser apparatus in a calibration operation. In other examples, this temperature may be set based on the type or class of laser apparatus. It may be intended that laser assemblies are regulated to this temperature during operation to meet a wavelength specification value for the light output thereby.

If the temperature is not equal to the set point (at least to within the tolerance), the method proceeds to block 408, which comprises regulating the temperature of the laser chip using a temperature regulation device which is capable of heating and cooling the laser chip, and the temperature regulation is based on a difference between the sensed temperature and at least one set point temperature. The temperature regulation device may comprise a thermoelectric device such as a Peltier device, as described above. The temperature regulation device may comprise one of the temperature regulation devices 106, 206 described above. The temperature regulation may for example comprise on/off control of the temperature regulation device, or may comprise pulse width modulation, or the like. The predetermined value may be the set point temperature. In some examples, the heater(s) may also be controlled to assist with temperature regulation, as further set out below.

If the temperature is equal to the set point (at least to within a predetermined tolerance), the target is reached and the method loops back to block 404. The temperature of the laser chip may be sensed periodically (for example, with a predetermined frequency) to ensure it is maintained at the set point. The method may continue during use of the laser assembly to produce laser light.

A selection of which of the heater or the temperature regulation device is used to regulate the temperature may be made as part of the method. For example, the temperature may be sensed or measured periodically (block 404) and a first set or proportion of these temperature measurements may, if the set point is not met, result in regulation of the heater. For example, the power (which may be an average power, for example provided using pulse width modulation) to the heater may be increased if the temperature is below the set point and decreased if the temperature is above the set point. In some examples, a higher proportion of the readings may result in regulation using the heater while a smaller proportion may result in regulation using the temperature regulation device. For example, in a series of ten temperature measurements, nine may be used as part of the heater control loop while one may be used as part of a temperature regulation device control loop. In some examples, a particular temperature measurement may result in control of both the heater and the temperature regulation device. In an example system, a temperature measurement may be acquired on the order of every second, or every few seconds, depending on the heat transfer properties of the system, the response time of the heater and/or the temperature regulation device and the like.

FIG. 5 shows another method for regulating the temperature in a laser assembly, for example the laser assembly of FIG. 2, or laser assemblies having components described in relation to FIG. 1A, 1B or 2.

Block 502 comprises sensing the ambient temperature. For example, this may be sensed using an environmental temperature sensor such as the environmental temperature sensor 214 of FIG. 2. Block 504 comprises determining if the determined ambient temperature is greater than or equal to a first set point (set point 1). If the ambient temperature is below the first set point then the laser chip is heated using at least one heater (block 506). The first set point may be a predetermined temperature below which additional heating assistance may be useful to operate the laser efficiently, and/or a temperature which places the laser in a temperature range within a temperature difference of the operating temperature that a temperature regulation device of the laser assembly can provide. If the ambient temperature is above the first set point, it may not be necessary to heat the laser chip using the heater(s), and the method may proceed directly to block 508 without heating the laser chip using the heater(s).

Block 508 comprises sensing the temperature of a laser chip, for example as described in relation to block 404. The target temperature of the laser chip is a second set point (set point 2). In block 510, it is determined whether the temperature of the laser chip is equal to a second set point, at least to within a predetermined tolerance. If so, the target is reached and the method loops back to block 508, such that the temperature of the laser chip is sensed periodically to ensure it is maintained at or near the second set point. If the temperature of the laser chip is above or below the second set point temperature or temperature range, the method proceeds to block 512 which comprises regulating the temperature of the laser chip using the temperature regulation device. In some examples, the second temperature set point is higher than the first temperature set point.

In some examples, the heater(s) may continue to be used to heat the laser chip after block 506. For example, the heater(s) may be controlled such that the laser chip may be expected, given the ambient temperature and the power supplied to the heater(s), to have a predetermined temperature. For example, this may be a control setting modelled in a calibration operation, or determined based on theoretical modelling or the like. In other examples, the temperature profile of the laser chip during use of the heater in block 506 may be monitored, and the heater(s) may be controlled according to the difference between the temperature and the first set point (or some other target temperature), for example using a Proportional Integral Derivative (PID) controller. Such a control method may mean that the heater(s) are supplying approximately the correct amount of heat for the laser chip to maintain the target temperature as it is reached. Moreover, the heater(s) may be controlled to provide sufficient heat that, absent the operation of the temperature regulation device, the laser chip would maintain such a target temperature.

Moreover, while a first control loop (block 502-506) in which the heater is used is shown separately from a second loop (block 508 to 512) in which the temperature regulation device is used, these loops may interact. For example, should the ambient temperature change, the output of the heater(s) may also be controlled to change the amount of heat output. The first control loop may however be carried out less frequently than the second control loop in such an example, as the ambient temperature is likely to vary relatively slowly. However, the second control loop may be carried out relatively frequently to ensure wavelength precision of the laser assembly.

In other examples, the heater may also be controlled based on the laser chip sensor, for example as described in relation to block 408 of FIG. 4.

Example methods may therefore comprise controlling the heater(s) according to a first control loop and controlling the temperature regulation device according to a second control loop. In some examples, the first control loop has a larger tolerance with respect to the first set point than the second control loop has with respect to the second set point temperature. For example, the first control loop may allow a tolerance of ±8° C., whereas the second control loop may allow a tolerance of ±1° C. The first and second set point temperatures may be the same, or may differ from one another. In some examples, the first and second control loops may be carried out with different repetition rates. For example, the first control loop may be carried out every X seconds whereas the second control loop may be carried out every Y seconds, where X is greater (longer) than Y.

FIG. 6 illustrates a further method of temperature regulation of a laser chip, for example a laser chip of a laser assembly as described in relation to FIG. 1A, 1B or 2.

Block 602 comprises heating a laser chip using at least one heater. Block 604 comprises sensing the temperature of the laser chip. In block 606, it is determined if the temperature of the laser chip is within a first tolerance of the first set point. On first initiation of the method, the laser chip may initially be below the temperature, and therefore the condition is likely to be satisfied once the temperature of the laser chip reaches the first set point minus the first tolerance. If not, the laser chip is further heated using the heater(s) (block 602) until the condition is satisfied. As the method progresses however, it may be that the temperature measured is higher than the first set point plus the first tolerance, in which case the heat output by the heater(s) may be reduced, for example by reducing the amount of power supplied thereto. If or once the temperature of the laser chip is at least the first set point minus the first tolerance, the temperature of the laser chip is further regulated using a temperature regulation device (block 608). However, the heater(s) continue to be operated to maintain a temperature of the laser chip during the blocks of the method described below. For example, the heater(s) may be regulated based on a proportion of the temperature measurements of the laser chip, or may be regulated according to modelled or calibrated settings, or settings used by a PID controller as the temperature approaches the first set point, to maintain a temperature around the first set point, as discussed above.

Block 610 comprises sensing the temperature of the laser chip. In block 612, it is determined whether the temperature is within a second tolerance of the second set point (set point 2±tolerance 2), as that indicates that the laser chip is within an appropriate tolerance of the set point temperature. If so, the method loops back to block 604, and the temperature will continue to be monitored to ensure it is maintained. The first tolerance may be greater than the second tolerance. If however the temperature is determined to be outside of the second tolerance of the second set point temperature, the method loops back to block 608 and the temperature of the laser chip continues to be regulated using the temperature regulation device.

In some examples, therefore, the heater(s) may be controlled according to a first control loop and the temperature regulation device may be controlled according to a second control loop. The first control loop may have a larger tolerance than the second control loop. In some examples, the second set point temperature is higher than the first set point temperature, or the set point temperatures may be the same.

For example, a laser assembly may be characterized as having an operating temperature of 52° C. to produce an intended wavelength of light. The first set point may be 52° C., and the first tolerance may be 4° C. Therefore a temperature in the range 48° C. to 56° C. will satisfy the condition of block 606, resulting in the temperature regulation device being used in block 608. The second set point may also be 52° C. and the second tolerance may be 1° C. Therefore a temperature in the range 51° C. to 53° C. may satisfy the condition of block 612.

FIG. 7 shows further method of temperature regulation of a laser chip, for example a laser chip of a laser assembly as described in relation to FIG. 1A, 1B or 2. In particular, FIG. 7 shows an example in which the control loops for a heater and a temperature regulation device are separate from one another. The ambient temperature is sensed in block 702 and it is determined if the ambient temperature is within a first tolerance of a first set point in block 704. If not, the heating of the laser chip using the heater(s) is adjusted (block 706). Control of the heater(s) may comprise simply turning the heater(s) on and off, or may comprise pulse width modulation or the like. The laser chip temperature is sensed in block 708 and it is determined if the ambient temperature is within a second tolerance of a second set point in block 710. If not, the heating of the laser chip using the temperature regulation device is adjusted (block 712). Setting the relative frequency of the control loops and the tolerance values can provide temperature convergence.

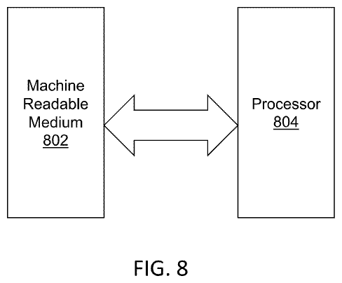

FIG. 8 illustrates a machine readable medium 802 encoding instructions which, when executed by a processor 804 of a laser assembly (for example, the laser assembly 100, 200 of FIGS. 1A and 1B, or of FIG. 2), may cause the processor 804 to carry out the methods described herein, for example as shown in FIGS. 4, 5, 6 and/or 7 to regulate a temperature of a laser assembly. The processor 804 may provide, or comprise part of, the controller 110, 210.

A processor (which includes one or more processors) may include a central processing unit (CPU), application specific integrated circuit (ASIC), field programmable gate array (FPGA) or the like. A memory may include one or several types of memory suitable for the processor, such as read-only memory (ROM), random-access memory, cache memory, flash memory devices, optical storage devices, solid state disk, hard disk drive, etc.

Any element or functionality of a described embodiment may be combined with or replace a corresponding element or functionality of another described embodiment.

The methods of the present disclosure may be implemented in hardware, or as software modules running on one or more processors. The methods may also be carried out according to the instructions of a computer program, and the present disclosure also provides a machine readable medium having stored thereon a program for carrying out any of the methods described herein. A computer program embodying the disclosure may be stored on a machine readable medium, or it could, for example, be in the form of a signal such as a downloadable data signal provided from an Internet website, or it could be in any other form.

The above-described embodiments are intended to be examples only. Alterations, modifications and variations may be effected to the particular embodiments by those of skill in the art without departing from the scope of the description, which is defined solely by the appended claims.

1. A laser assembly comprising:
a laser chip;
a heater;
a temperature regulation device capable of heating and cooling the laser chip;
at least one temperature sensor configured to measure a temperature of the laser assembly; and
a controller configured to, based on at least one temperature measured by the at least one temperature sensor;
control the heater to heat the laser chip; and
control the temperature regulation device to regulate the temperature of the heated laser chip.

2. The laser assembly of claim 1 wherein the controller is configured to control the heater using a first control loop and to control the temperature regulation device using a second control loop.

3. The laser assembly of claim 1 wherein the first control loop has a lower set point temperature than the second control loop.

4. The laser assembly of claim 1, where the heater comprises a first heater, and the laser assembly further comprises a second heater controlled by the controller to heat the laser chip.

5. The laser assembly of claim 4 wherein the first heater and second heater are positioned on opposite sides of the laser chip.

6. The laser assembly of claim 1, wherein the at least one temperature sensor comprises a laser chip temperature sensor to measure a temperature of the laser chip, and wherein the controller is configured to:
control at least one of the heater and the temperature regulation device to heat the laser chip in response to a determination that the laser chip temperature is below a predetermined value; and
control the temperature regulation to regulate the temperature of the heated laser chip once the laser chip temperature has reached a predetermined value.

7. The laser assembly of claim 1, wherein the at least one temperature sensor comprises a laser chip temperature sensor and an environmental temperature sensor to measure an environmental temperature of the laser assembly, and wherein the controller is configured to:
control the heater to heat the laser chip in response to a determination that the environmental temperature is below a predetermined value; and
control the temperature regulation device to regulate the temperature of the heated laser chip once the laser chip temperature has reached a predetermined value.

8. The laser of claim 6 wherein at least one of the laser chip temperature sensor and the environmental temperature sensor is a thermistor.

9. The laser assembly of claim 1, wherein the heater is a resistor.

10. The laser assembly of claim 9 wherein the resistor is formed in a substrate supporting the laser chip.

11. The laser assembly of claim 1, wherein the temperature regulation device comprises a Peltier device.

12. The laser assembly of claim 1 which comprises an optical fiber telecommunications laser.

13. A method for regulating a temperature of a laser chip of a laser assembly comprising:
heating the laser chip using a heater of the laser assembly;
sensing a temperature of the laser chip; and
based on a difference between the sensed temperature and at least one set point temperature, controlling the temperature of the heated laser chip using a temperature regulation device which is capable of heating and cooling the laser chip.

14. The method of claim 13 further comprising, prior to heating the laser chip using the heater;
sensing a first temperature of at least one of the laser chip and an environmental temperature; and
heating the laser chip using the heater when the sensed first temperature is below a first temperature set point.

15. The method of claim 14 wherein controlling the temperature of the heated laser chip using the temperature regulation device comprises controlling the heated laser chip based on a second temperature set point, wherein the second temperature set point is higher than the first temperature set point.

16. The method of claim 13 further comprising controlling the heater according to a first control loop and controlling the temperature regulation device according to a second control loop.

17. The method of claim 16, wherein the first control loop has a larger temperature tolerance than the second control loop.

18. A machine readable medium encoding instructions which, when executed by a processor of a laser assembly, cause the processor to carry out the method of claim 13.
